(19) United States
(12) Patent Application Publication
(10) Pub. No.: US 2008/0122073 A1
(43) Pub. Date: May 29, 2008

(54) MEMS module package

(75) Inventor: Tzu-Yin Yen, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, LTD., Taichung (TW)

(21) Appl. No.: 11/987,743

(22) Filed: Dec. 4, 2007

(30) Foreign Application Priority Data
Sep. 8, 2006 (TW) 95216093

(51) Int. Cl. H01L 23/02

(52) U.S. Cl. 257/723; 257/E23.18

(57) ABSTRACT

A MEMS module package includes a substrate, a cap capped on the substrate and defining with the substrate an accommodation chamber, a micro-electromechanical chip mounted on the substrate within the accommodation chamber, a plurality of passive components mounted on the substrate within the accommodation chamber and electrically connected to the micro-electromechanical chip.

### BACKGROUND OF THE INVENTION

1. Field of the Invention

The present invention relates to micro-electro-mechanical system (hereinafter referred to as “MEMS”) modules and more particularly, to a MEMS module package including passive components.

2. Description of the Related Art

Micro-Electro-Mechanical System (MEMS) is the integration of mechanical elements, sensors, actuators, and electronics on a common silicon substrate through micro-fabrication technology. To improve the performance of a MEMS module, mechanical support strength, environmental factors, such as interference of noises, electrical connection condition, heat resistivity, and many other factors must be taken into account during packaging.

Conventionally, a micro-electromechanical module is packaged with a metal cap by means of cap package. FIG. 1 illustrates a micro-electromechanical module package according to a design of prior art. This design comprises a substrate 1, a micro-electromechanical chip 3 mounted on the substrate 1, and a cap 2 covered on the substrate 1 to shield the micro-electromechanical chip 3. This cap package has only the micro-electromechanical chip 3 packed on the inside. During application, the micro-electromechanical module package must be used with other external micro-electromechanical modules and related passive components for working. Thus, the whole micro-electromechanical module has a large dimension, and the whole micro-electromechanical module is expensive.

Therefore, it is desirable to provide a MEMS module package that eliminates the aforesaid drawbacks.

### SUMMARY OF THE INVENTION

The present invention has been accomplished under the circumstances in view. It is therefore one object of the present invention to provide a MEMS module package, which has small-size and low-cost characteristics.

To achieve this object of the present invention, the MEMS module package comprises a substrate; a cap capped on the substrate and defining with the substrate an accommodation chamber; at least one micro-electromechanical chip mounted on the substrate within the accommodation chamber; and a plurality of passive components mounted on the substrate within the accommodation chamber and electrically connected to the at least one micro-electromechanical chip.

The invention has passive components packaged therein. Comparing to the conventional package, the invention reduces the number of times in packaging, thereby saving much processing time, i.e., the MEMS module package has small-size and low-cost characteristics.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing of a micro-electromechanical module package according to a prior art;

FIG. 2 is a schematic drawing showing a micro-electromechanical chip mounted on a substrate in accordance with a first embodiment of the present invention;

FIG. 3 is schematic drawing showing two passive components mounted on the substrate;

FIG. 4 is a schematic drawing showing two support members mounted on the substrate;

FIG. 5 is a schematic drawing showing a cap covered on the substrate;

FIG. 6 is a schematic drawing showing a micro-electromechanical chip with attached support members mounted on a substrate in accordance with a second embodiment of the present invention;

FIG. 7 is a schematic drawing showing two passive components mounted on the substrate;

FIG. 8 is a schematic drawing showing parts of a cap fastened to the substrate;

FIG. 9 is a schematic drawing showing that the cap is capped on the substrate, and

FIG. 10 is a schematic drawing of a MEMS module package in accordance with a third embodiment of the present invention.

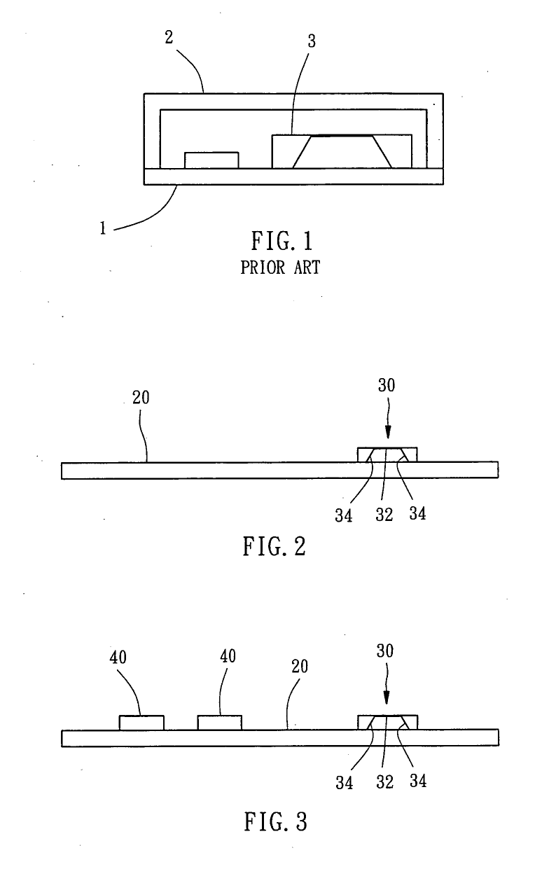

### DETAILED DESCRIPTION OF THE INVENTION

Referring to FIGS. 2-5, a MEMS module package 10 in accordance with a first embodiment of the present invention is shown comprised of a substrate 20, a micro-electromechanical chip 30, two passive components 40, a cap 50, and two support members 60.

The substrate 20 can be an epoxy-based substrate, organic fiber glass substrate, glass fiber board, polyphenylene ether-based substrate or ceramic substrate.

The micro-electromechanical chip 30 is installed on the substrate 20, having an active zone 32 and an inactive zone 34. The active zone 32 is a thin-film disposed at the center of the micro-electromechanical chip 30. The inactive zone 34 has a thickness greater than the active zone 32, and is arranged around the active zone 32 to surround the active zone 32.

The two passive components 40 are arranged on the substrate 20 and electrically connected to the micro-electromechanical chip 30.

The cap 50 is a metal-coated plastic member capped on the substrate 20, thereby defining an accommodation chamber 52. The micro-electromechanical chip 30 and the passive components 40 are disposed inside the accommodation chamber 52. The cap 50 has a through hole 54 at the top side corresponding to the active zone 32 of the micro-electromechanical chip 30, for allowing communication of active zone 32 with ambient atmosphere. In addition, the cap can be fastened to the substrate by means of thermal compression bonding, chemical adhesive bonding, or tenon-and-mortise coupling.

The two support members 60 are set between the substrate 20 and the cap 50 and arranged at two sides relative to the micro-electromechanical chip 30 to protect the cap 50 against deformation upon an accidental external force.

Referring to FIGS. 2-5 again, the packaging procedure of the MEMS module package 10 includes the following steps.

1. Affix the inactive zone 34 of the micro-electromechanical chip 30 to the top side of the substrate 20 (see FIG. 2).

2. Arrange the passive components 40 on the substrate 20, and electrically connect the passive components 40 to the micro-electromechanical chip 30 (see FIG. 3).

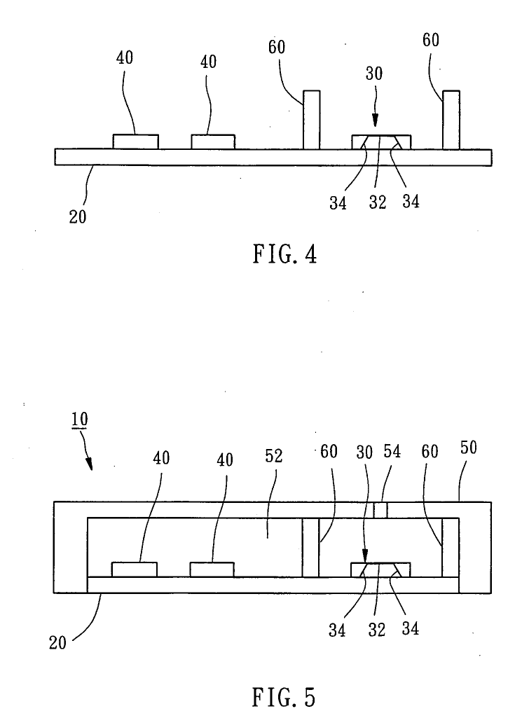

3. Fasten the two support members 60 to the substrate 20 by means of chemical bonding, keeping the support members 60 disposed at two sides relative to the micro-electromechanical chip 30 and spaced from each other at a predetermined distance (see FIG. 4).

4. Affix the cap 50 to the substrate 20 by chemical bonding (see FIG. 5).

As stated above, the MEMS module package 10 has related passive components packed therein. Comparing to the conventional package, the invention reduces the number of times in packaging, thereby saving much processing time, i.e., the MEMS module package 10 has small-size and low-cost characteristics. Further, the structural design of the present invention is applicable to the environment where the active zone 32 has to be exposed to the outside for measuring.

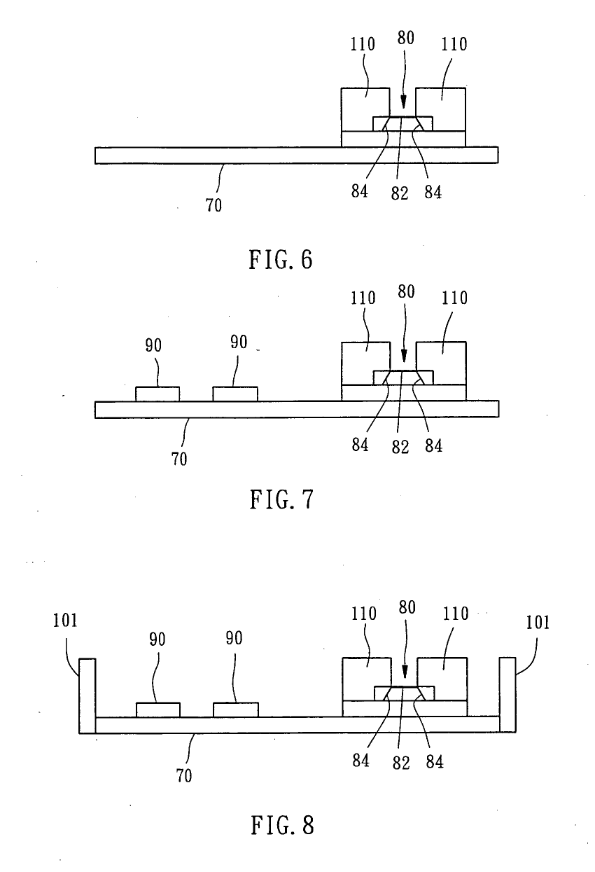

FIGS. 6-9 show a MEMS module package 12 in accordance with a second embodiment of the present invention. According to this second embodiment, the MEMS module package 12 comprises a substrate 70, a micro-electromechanical chip 80, two passive components 90, a cap 100, and two support members 110.

The substrate 70 can be prepared from epoxy, organic fiber glass substrates, glass fiber board, polyphenylene ether (PPE), or ceramic. According to this embodiment, the substrate 70 is prepared from glass fiber board.

The micro-electromechanical chip 80 is installed on the substrate 70, having an active zone 62 and an inactive zone 84. The active zone 82 is a thin-film disposed at the center of the micro-electromechanical chip 80. The inactive zone 84 has a thickness greater than the active zone 82, and is arranged around the active zone 82 to surround the active zone 82.

The two passive components 90 are arranged on the substrate 70 and electrically connected to the micro-electromechanical chip 80.

The cap 100 is formed of multiple metal plate members 101 bonded to one another and capped on the substrate 70, thereby defining an accommodation chamber 102. The micro-electromechanical chip 80 and the passive components 90 are disposed inside the accommodation chamber 82. The cap 100 has a through hole 104 at the top side corresponding to the active zone 82 of the micro-electromechanical chip 80.

The two support members 110 are made of composite materials by molding. Before packaging, the support members 110 are molded on the micro-electromechanical chip 80 to surround the inactive zone 84 for supporting the cap 100 against deformation upon an accidental external force.

Referring to FIGS. 6-9 again, the packaging procedure of the MEMS module package 12 includes the following steps.

1. Affix the inactive zone 84 of the micro-electromechanical chip 80 to the top side of the substrate 70 (see FIG. 6).

2. Arrange the passive components 90 on the substrate 70, and electrically connect the passive components 90 to the micro-electromechanical chip 80 (see FIG. 7).

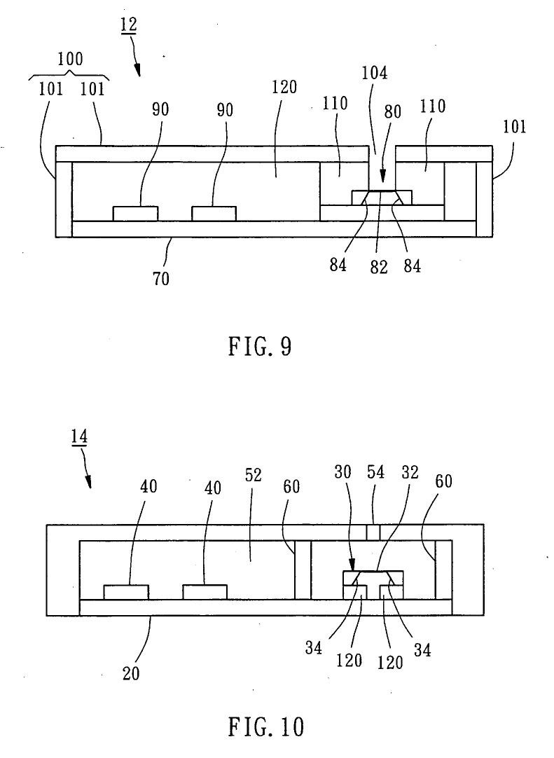

3. Affix the cap 100 to the substrate 70 by chemical bonding (see FIGS. 8 and 9), keeping the support members 110 stopped between the substrate 70 and the cap 100.

As stated above, the MEMS module package 12 has related passive components packed therein. This second embodiment is substantially similar to the aforesaid first embodiment with the exception of the arrangement of the support members 110. Therefore, this second embodiment achieves the same effects of the aforesaid first embodiment, and has small-size and low-cost characteristics.

FIG. 10 shows a MEMS module package 14 in accordance with a third embodiment of the present invention. Similar to the aforesaid first embodiment, the MEMS module package 14 of this second embodiment comprises a substrate 20, a micro-electromechanical chip 30, two passive components 40, a cap 50, and two support members 60. The only difference between this second embodiment and the aforesaid first embodiment is that the second embodiment has an ITO (indium tin oxide) conductive glass 120 set between the substrate 20 and the micro-electromechanical chip 30 to electrically connect the micro-electromechanical chip 30 to the substrate 20. This embodiment is suitable for the application of any of a variety of micro-electromechanical chips. Further, this third embodiment achieves the same effects of the aforesaid first and second embodiments, and has small-size and low-cost characteristics.

In conclusion, the above-described various embodiments of the present invention have the following advantages:

1. The invention has related passive components packaged therein, saving much packing time and, having small-size and low-cost characteristics.

2. The invention is applicable to the environment where the active zone of the micro-electromechanical chip has to be exposed to the outside for measuring.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A MEMS module package comprising:
a substrate;
a cap capped on the substrate and defining with the substrate an accommodation chamber;
at least one micro-electromechanical chip mounted on the substrate and located within the accommodation chamber; and
a plurality of passive components mounted on the substrate, located within the accommodation chamber and electrically connected to the at least one micro-electromechanical chip.

2. The MEMS module package as claimed in claim 1, wherein the at least one micro-electromechanical chip has an active zone; one of the substrate and the cap has a through hole corresponding to the active zone of the at least one micro-electromechanical chip.

3. The MEMS module package as claimed in claim 2, wherein the active zone is a thin film.

4. The MEMS module package as claimed in claim 1, wherein the cap is made of a metal material.

5. The MEMS module package as claimed in claim 1, wherein the cap is made of a plastic material coated with a layer of metal coating.

6. The MEMS module package as claimed in claim 1, wherein the cap is formed of a plurality of metal plate members.

7. The MEMS module package as claimed in claim 1, wherein the cap is fastened to the substrate by means of one method selected from the group consisting of thermal compression bonding, chemical adhesive bonding, and tenon-and-mortise coupling.

8. The MEMS module package as claimed in claim 1, wherein the substrate is the one selected from the group consisting of epoxy-based substrate, organic fiber glass substrate, glass fiber board, polyphenylene ether-based substrate and ceramic substrate.

9. The MEMS module package as claimed in claim 1, further comprising a plurality of support members connected between the substrate and the cap.

10. The MEMS module package as claimed in claim 9, wherein the support members are formed of composite materials by molding.

11. The MEMS module package as claimed in claim 9, wherein the at least one micro-electromechanical chip has an inactive zone; the support members have a part thereof set between the substrate and the cap and encapsulating the inactive zone.

12. The MEMS module package as claimed in claim 1, further comprising an indium tin oxide conductive glass set between the substrate and the at least one micro-electromechanical chip and electrically connecting the at least one micro-electromechanical chip to the substrate.
